(19) United States
(12) Patent Application Publication
(10) Pub. No.: US 2014/0015148 A1
(43) Pub. Date: Jan. 16, 2014

(54) SEMICONDUCTOR PACKAGE AND METHOD OF MANUFACTURING THE SAME

(71) Applicant: Ju-hyun LYU, Cheonan-si (KR)

(72) Inventor: Ju-hyun LYU, Cheonan-si (KR)

(21) Appl. No.: 13/934,371

(22) Filed: Jul. 3, 2013

(30) Foreign Application Priority Data
Jul. 12, 2012 (KR) 10-2012-0076284

(51) Int. Cl. H01L 23/28; H01L 21/56

(52) U.S. Cl. CPC H01L 23/28; H01L 21/565
USPC 257/777; 257/734; 438/127

(57) ABSTRACT

A semiconductor package and a method of manufacturing the same are provided. The semiconductor package includes a circuit board, at least one semiconductor chip mounted on the circuit board, a spacer disposed on the at least one semiconductor chip, the spacer having a thickness of about 5 μm to about 110 μm, and an upper surface of the spacer exposed externally; and an encapsulant covering the at least one semiconductor chip. The semiconductor package may have a small thickness and may prevent incomplete molding that causes exposure of an active surface of a semiconductor chip.

### CROSS-REFERENCE TO RELATED APPLICATION

This application claims the benefit of Korean Patent Application No. 10-2012-0076284, filed on Jul. 12, 2012, in the Korean Intellectual Property Office, the disclosure of which is incorporated herein in its entirety by reference.

### BACKGROUND

The inventive concepts relate to semiconductor packages and methods of manufacturing the same, and more particularly, to thin semiconductor packages configured to prevent or mitigate incomplete molding, and methods of manufacturing the same.

Demands for reducing the thickness of semiconductor packages are increasing, and thus research is being broadly conducted to reduce the number of stacked semiconductor chips by increasing the integration density of devices within a unit area, or to reduce the thickness of the stacked semiconductor chips.

Meanwhile, research is also being conducted to reduce the distance between an upper surface of a top semiconductor chip among semiconductor chips stacked in one semiconductor package, and an upper surface of an encapsulant of the semiconductor package.

### SUMMARY

Some of the inventive concepts provide thin semiconductor packages configured to prevent or mitigate incomplete molding, which results in exposure of an active surface of a semiconductor chip.

Some of the inventive concepts also provide methods of manufacturing thin semiconductor packages that are configured to prevent or mitigate incomplete molding, which results in exposure of an active surface of a semiconductor chip.

According to an example embodiment, a semiconductor package includes a circuit board, at least one semiconductor chip mounted on the circuit board, a spacer disposed on the at least one semiconductor chip, and an encapsulant covering or surrounding the at least one semiconductor chip. The spacer may have a thickness of about 5 μm to about 110 μm , and an upper surface of the spacer may be exposed externally. The spacer may be formed of a polymer, metal, or silicon. For example, the spacer may be formed by stacking two or more layers formed of a polymer, metal, or silicon.

The upper surface of the spacer and an upper surface of the encapsulant may be substantially coplanar. A horizontal distance between an edge of the spacer and an edge of the at least one semiconductor chip on which the spacer is disposed may be equal to or less than about 200 μm. At least a portion of the edge of the spacer may protrude outside the at least one semiconductor chip on which the spacer is disposed. At least a portion of the edge of the spacer may be disposed on an upper surface of the at least one semiconductor chip on which the spacer is disposed.

At least a portion of side surfaces of the spacer may be inclined inward in a direction away from the at least one semiconductor chip. A transverse width of the spacer may be reduced in a direction away from the at least one semiconductor chip. At least a portion of side surfaces of the spacer may be recessed inward. The at least a portion of the side surfaces of the spacer may be curved or concaved inward.

At least a portion of side surfaces of the spacer may be configured to be rougher than the upper surface of the spacer.

At least a portion of side surfaces of the spacer may be stepped such that a width of an upper portion of the spacer is less than a width of a lower portion of the spacer.

The at least one semiconductor chip may include at least two stacked semiconductor chips. The at least two stacked semiconductor chips may include at least one flip-chip. A top semiconductor chip among the at least two stacked semiconductor chips may include a connection terminal on its upper surface.

The encapsulant may leave flash on at least a portion of the upper surface of the spacer. An area of a lower surface of the spacer may be greater than an area of an upper surface of the at least one semiconductor chip on which the spacer is disposed.

According to an example embodiment, a semiconductor package including a circuit board, at least one semiconductor chip mounted on the circuit board, a spacer disposed on the at least one semiconductor chip, and an encapsulant covering the at least one semiconductor chip, an upper surface of the encapsulant and an upper surface of the spacer are substantially coplanar.

An upper surface of the spacer may be exposed externally. At least a portion of an edge of the spacer may be at least one of slightly bend downward and slightly bent toward the at least one semiconductor chip. Side surfaces of the spacer may include a roughened surface or burrs. The spacer may have a thickness of about 5 μm to about 110 μm

According to an example embodiment, a method of manufacturing a semiconductor package includes mounting at least one semiconductor chip on a circuit board, disposing a spacer on an upper surface of the at least one semiconductor chip, and supplying an encapsulant to seal side surfaces and an exposed portion of the upper surface of the at least one semiconductor chip while a mold contacts the spacer.

According to an example embodiment, a system includes a control unit, an input/output (I/O) unit configured to input or output data, a memory unit configured to store the data, an interface unit configured to transmit or receive the data to or from an external apparatus, and a bus configured to connect the control unit, the I/O unit, the memory unit, and the interface unit to communicate with each other, wherein at least one of the control unit and the memory unit includes one of the above semiconductor packages.

According to an example embodiment, a semiconductor package includes a circuit board, at least one semiconductor chip on the circuit board, at least one spacer attached to an upper surface of the at least one semiconductor chip; and an encapsulant covering the at least one semiconductor chip. The semiconductor package may further include a bonding layer between the at least one spacer and the at least one semiconductor chip. The bonding layer may attach the at least one spacer to the at least one semiconductor chip.

An upper surface of the encapsulant and an upper surface of the at least one spacer may be substantially coplanar with a tolerance of about 2 μm.

The at least one spacer may be formed of a single spacer. A distance between an edge of an uppermost one of the at least one semiconductor chip and an edge of the single spacer may be configured such that an encapsulant flows to reach the edge of the single spacer at a predetermined pressure.

An entire edge of the at least one spacer may protrude from an entire edge of an uppermost one of the at least one semiconductor chip. The at least one spacer include an opening and the opening is configured to ensure a space where connectors are connected to bonding pads of the uppermost one of the at least one semiconductor chip.

### BRIEF DESCRIPTION OF THE DRAWINGS

Example embodiments will be more clearly understood from the following detailed description taken in conjunction with the accompanying drawings in which:

FIG. 1A is a perspective view of a semiconductor package according to an example embodiment;

FIG. 1B is a cross-sectional view taken along the line B-B′ of FIG. 1A;

FIG. 2 is a flowchart of a method of manufacturing the semiconductor package illustrated in FIGS. 1A and 1B, according to an example embodiment;

FIGS. 3A through 3C are sequential cross-sectional views for describing a method of manufacturing the semiconductor package illustrated in FIGS. 1A and 1B, according to an example embodiment;

FIG. 4 is a perspective view of the semiconductor package illustrated in FIG. 3C, when flash remains on an upper surface of a spacer;

FIG. 5A is a cross-sectional view of a semiconductor package according to an example embodiment;

FIGS. 5B and 5C are conceptual cross-sectional views for describing a method of forming a spacer to be used in the semiconductor package illustrated in FIG. 5A;

FIG. 5D is a cross-sectional view of a modified example of the semiconductor package illustrated in FIG. 5A;

FIG. 6A is a cross-sectional view of a semiconductor package according to an example embodiment;

FIGS. 6B and 6C are conceptual cross-sectional views for describing a method of forming a spacer to be used in the semiconductor package illustrated in FIG. 6A;

FIG. 7A is a cross-sectional view of a semiconductor package according to an example embodiment;

FIGS. 7B and 7C are conceptual cross-sectional views for describing a method of forming a spacer to be used in the semiconductor package illustrated in FIG. 7A;

FIGS. 8A through 8C are plan views of semiconductor packages according to example embodiments;

FIGS. 9A through 9D are cross-sectional views of semiconductor packages according to example embodiments;

FIG. 10 is a perspective view of first through sixth semiconductor chips stacked and electrically connected to each other by using side interconnection, before being encapsulated with an encapsulant, according to an example embodiment;

FIG. 11 is a block diagram of a memory card including the above semiconductor package, according to an example embodiment; and

FIG. 12 is a conceptual view of a system according to an example embodiment.

### DETAILED DESCRIPTION OF THE EMBODIMENTS

Hereinafter, the inventive concepts will be described in detail by explaining example embodiments with reference to the attached drawings. The inventive concepts may, however, be embodied in many different forms and should not be construed as being limited to the embodiments set forth herein; rather, these example embodiments are provided so that this disclosure will be thorough and complete, and will fully convey the inventive concepts to one of ordinary skill in the art. In the drawings, like reference numerals denote like elements. Furthermore, various elements and regions are schematically illustrated. Accordingly, the inventive concepts are not limited to relative sizes or distances in the drawings.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the inventive concept.

The terminology used herein is for the purpose of describing particular embodiments and is not intended to limit the inventive concepts. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing.

Unless defined differently, all terms used in the description including technical and scientific terms have the same meaning as generally understood by one of ordinary skill in the art. Terms as defined in a commonly used dictionary should be construed as having the same meaning as in an associated technical context, and unless defined in the description, the terms are not ideally or excessively construed as having formal meaning.

As used herein, the team “and/or” includes any and all combinations of one or more of the associated listed items.

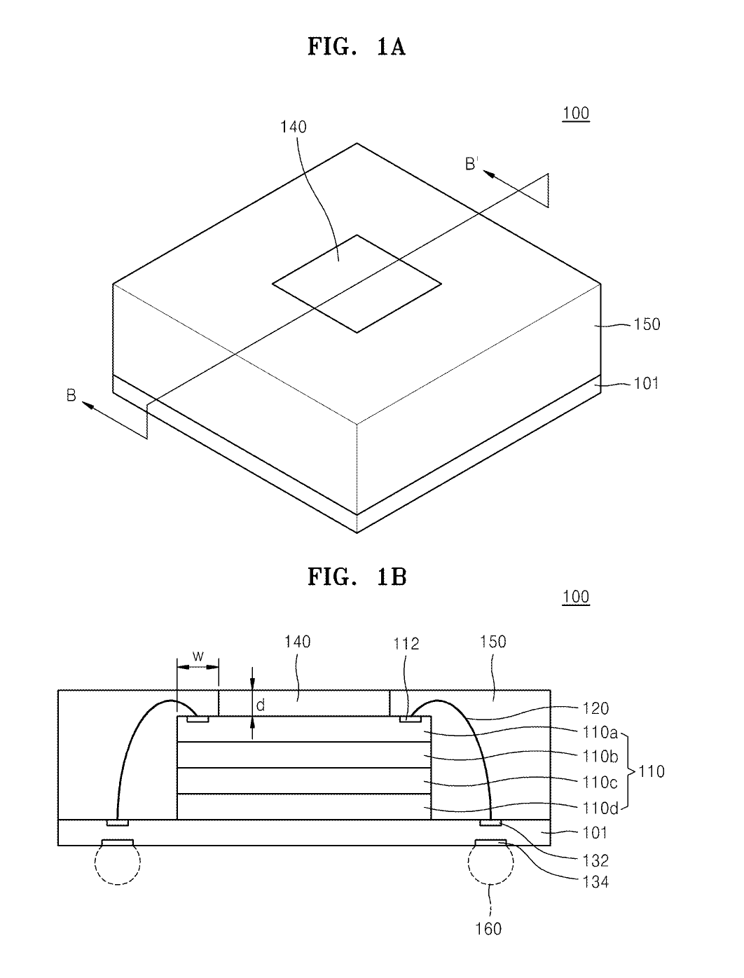

FIGS. 1A and 1B are a perspective view and a cross-sectional view of a semiconductor package 100 according to an example embodiment, respectively. FIG. 1B is a cross-sectional view taken along the line B-B′ of FIG. 1A.

Referring to FIGS. 1A and 1B, the semiconductor package 100 may include at least one semiconductor chip 110 mounted on a circuit board 101, and a spacer 140 disposed on the semiconductor chip 110. The semiconductor chip 110 may be electrically connected to the circuit board 101 via connectors 120, and may be encapsulated with an encapsulant 150 to protect the package 100 from, for example, external impact, temperature, and moisture.

The circuit board 101 may be an insulating substrate, on which conductive circuits are formed, for example, a rigid printed circuit board (RPCB), a flexible printed circuit board (FPCB), or a tape substrate.

The semiconductor chip 110 may be one semiconductor chip or may include a plurality of stacked semiconductor chips, for example, first through fourth semiconductor chips 110a through 110d, as illustrated in FIG. 1B. Although the first through fourth semiconductor chips 110a through 110d are vertically aligned in FIG. 1B, in some cases, the first through fourth semiconductor chips 110a through 110d may be stacked offset.

The semiconductor chip 110 may be connected to the circuit board 101 via the connectors 120. The connectors 120 may be any means for electrically connecting two connection terminals, and may be, but not limited to, bonding wires as illustrated in FIG. 1B, solder balls, or solder bumps. In the semiconductor package 100, bonding wires, solder balls, solder bumps, or a combination thereof may be used as the connectors 120. For example, where the first semiconductor chip 110a that is a top semiconductor chip is connected to the circuit board 101 via bonding wires, the bonding wires may extend from the first semiconductor chip 110a upward to a desired (or alternatively, predetermined) height and then may extend downward to be bonded to a plurality of bonding pads 132 on the circuit board 101.

The spacer 140 may be formed on the semiconductor chip 110. The spacer 140 may be disposed at the center of an upper surface of the semiconductor chip 110. For example, the spacer 140 may be disposed before a molding process of the semiconductor chip 110. Thus, during the molding process, a burden to flow the encapsulant 150 to reach the center of the upper surface of the semiconductor chip 110 in a mold for the molding process may be substantially relieved. For example, at a given feeding pressure, the encapsulant does not have to be fed to reach the center of the upper surface of the semiconductor chip 110 because the encapsulation completes when the encapsulant reaches side surfaces of the spacer 140. Detailed descriptions thereof will be provided below.

The spacer 140 may be formed of, for example, silicon, metal, or plastic. For example, the spacer 140 may be formed of epoxy resin. Also, the spacer 140 may be formed of a single material, or a composite of silicon, metal, and/or plastic. If the spacer 140 is formed of a composite of two or more different materials, the materials may be stacked on one another or the material may be formed such that powder of one material is dispersed in a matrix of the other material.

A thickness d of the spacer 140 may be, for example, about 5 μm to about 110 μm Alternatively, the thickness d of the spacer 140 may be, for example, about 20 μm all to about 70 μm.

The spacer 140 is not limited to a certain size. For example, the size of the spacer 140 may be determined such that a horizontal distance w between an edge of the spacer 140 and an edge of the first semiconductor chip 110a on which the spacer 140 is disposed is equal to or less than about 200 μm. Alternatively, the size of the spacer 140 may be determined such that the horizontal distance w is, for example, equal to or less than about 150 μm, or equal to or less than about 100 μm.

A bonding layer for bonding the spacer 140 onto the semiconductor chip 110 may be further formed between the spacer 140 and the semiconductor chip 110. The bonding layer may be formed of, for example, a non-conductive film (NCF), an anisotropic conductive film (ACF), an ultraviolet (UV)-sensitive film, an instant adhesive, a thermosetting adhesive, a laser-curable adhesive, an ultrasound-curable adhesive, or non-conductive paste (NCP).

The encapsulant 150 may be formed of a polymer such as resin. For example, the encapsulant 150 may be, but not limited to, an epoxy molding compound (EMC). The encapsulant 150 may encapsulate lateral and upper surfaces of the semiconductor chip 110.

Also, a level of an upper surface of the encapsulant 150 may be substantially the same as the level of an upper surface of the spacer 140. Here, the fact that the upper surface of the encapsulant 150 and the upper surface of the spacer 140 have substantially the same level means that the difference between the highest level on the upper surface of the encapsulant 150 and the highest level on the upper surface of the spacer 140 is within about 2 μm.

The bonding pads 132 on an upper surface of the circuit board 101 may be electrically connected via circuits to a plurality of bump pads 134 on a lower surface of the circuit board 101. The bump pads 134 may be connected to solder bumps 160, which may be connected to, for example, an external device.

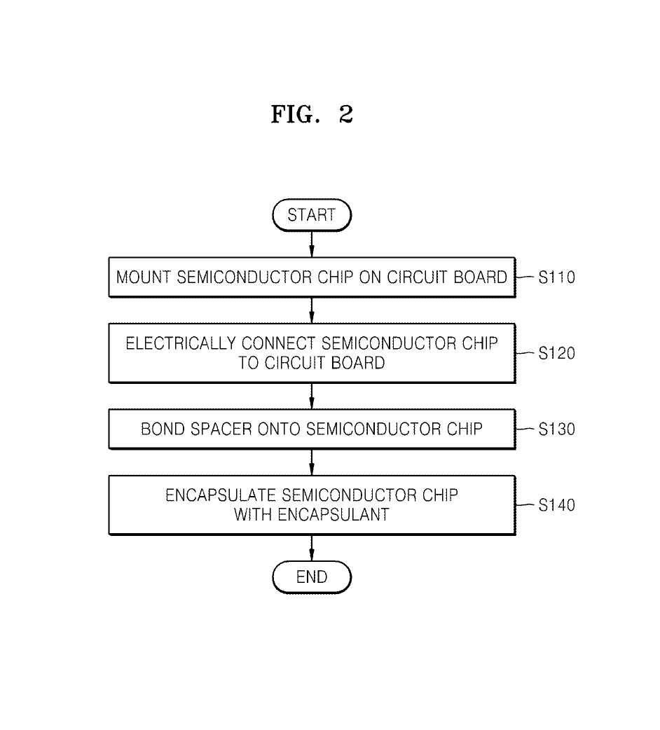

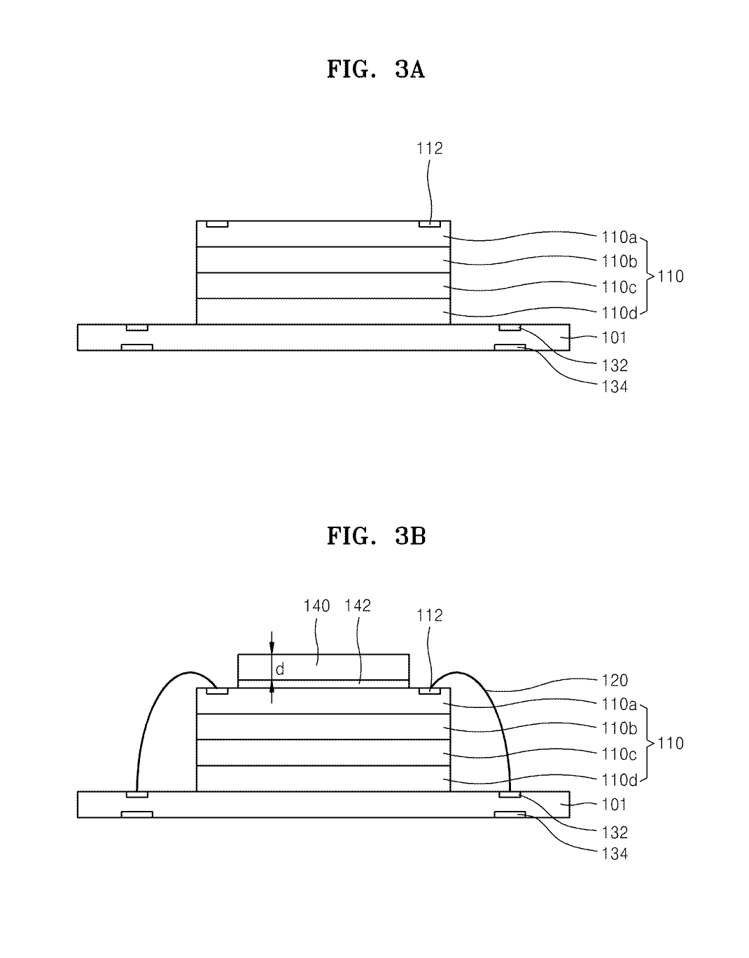

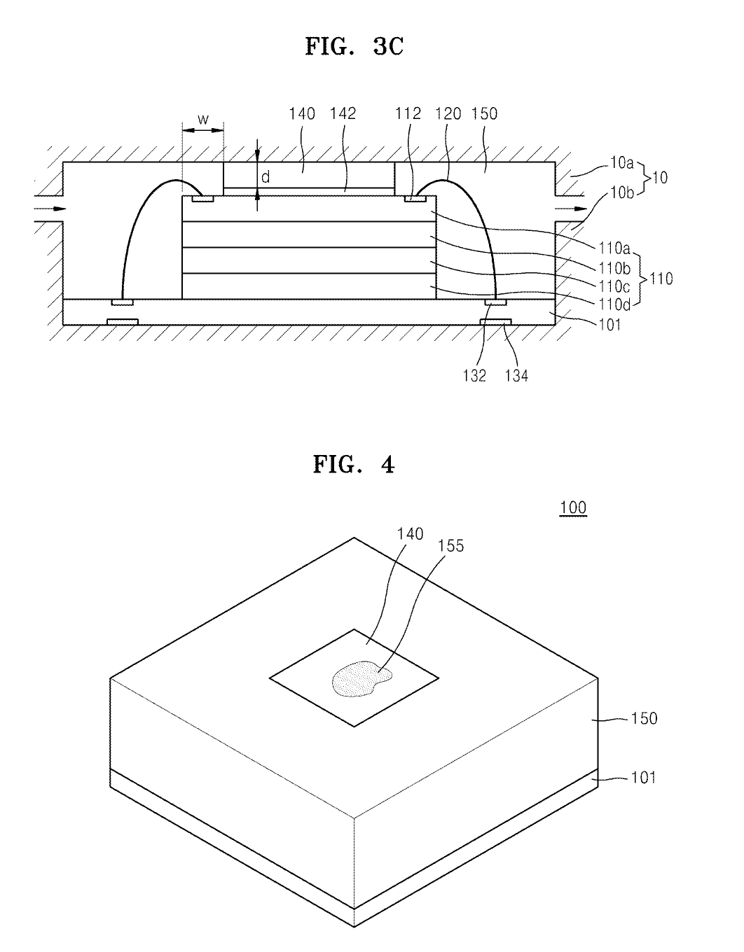

FIG. 2 is a flowchart of a method of manufacturing the semiconductor package 100 illustrated in FIGS. 1A and 1B, according to an example embodiment. FIGS. 3A through 3C are sequential cross-sectional views for describing a method of manufacturing the semiconductor package 100 illustrated in FIGS. 1A and 1B, according to an example embodiment.

Referring to FIGS. 2 and 3A, the semiconductor chip 110 is mounted on the circuit board 101 (S110). The semiconductor chip 110 may be mounted on the circuit board 101 by using various methods, for example, a method using a bonding member such as an NCF, an ACF, a UV-sensitive film, an instant adhesive, a thermosetting adhesive, a laser-curable adhesive, an ultrasound-curable adhesive, or NCP.

The semiconductor chip 110 may be a single semiconductor chip or may include the first through fourth semiconductor chips 110a through 110d as illustrated in FIG. 3A. Also, at least one of the first through fourth semiconductor chips 110a through 110d may be mounted in the form of a flip-chip of which an active surface faces downward.

The circuit board 101 may include a metal pattern and vias for interlayer connection. Here, the metal pattern may include a single layer or a plurality of layers. The circuit board 101 may be an RPCB, an FPCB, or a tape substrate.

The bonding pads 132 electrically connected to the metal pattern may be formed on the upper surface of the circuit board 101.

The bump pads 134 electrically connected to the bonding pads 132 may be formed on the lower surface of the circuit board 101. The bump pads 134 may be electrically connected to an external device via a plurality of connection terminals (e.g., the solder bumps 160 illustrated in FIG. 1B). The external device may be, but not limited to, for example, another substrate such as a main board.

Referring to FIGS. 2 and 3B, the semiconductor chip 110 is electrically connected to the circuit board 101 via the connectors 120 (S120). Here, although bonding wires are illustrated as the connectors 120 in FIG. 3B, the connectors 120 are not limited thereto. For example, the semiconductor chip 110 may be connected to the circuit board 101 via through silicon vias (TSV). Detailed descriptions thereof will be provided below.

After that, the spacer 140 may be disposed and bonded onto the semiconductor chip 110 (S130). Although it has been described that the spacer 140 is bonded onto the semiconductor chip 110 after the semiconductor chip 110 has been electrically connected to the circuit board 101 in FIG. 2, it is not necessary to do so. However, the process of bonding the spacer 140 onto the semiconductor chip 110 is not limited thereto as long as the process is performed before an encapsulation process (S140). For example, the spacer 140 may be bonded onto the semiconductor chip 110 before the semiconductor chip 110 is electrically connected to the circuit board 101. Alternatively, the spacer 140 may be bonded onto the semiconductor chip 110 and then the semiconductor chip 110 may be mounted on the circuit board 101.

In order to bond the spacer 140 onto the semiconductor chip 110, a bonding layer 142 may be further formed between the spacer 140 and the semiconductor chip 110. The bonding layer 142 may be formed of, for example, an NCF, an ACF, a UV-sensitive film, an instant adhesive, a thermosetting adhesive, a laser-curable adhesive, an ultrasound-curable adhesive, or NCP. As described above referring to FIGS. 1A and 1B, the thickness d of the spacer 140 may be, for example, about 5 μm to about 110 μm. Alternatively, the thickness d of the spacer 140 may be, for example, about 20 μm to about 70 μm.

Referring to FIGS. 2 and 3C, the encapsulant 150 encapsulates the side surfaces and an exposed portion of the upper surface of the semiconductor chip 110 (S140). For this, the circuit board 101 on which the semiconductor chip 110 is mounted may be disposed in an encapsulation mold 10. For example, the encapsulation mold 10 may include an upper mold 10a and a lower mold 10b, and the upper mold 10a may be configured to closely contact the upper surface of the spacer 140.

In order to encapsulate the semiconductor chip 110, a polymer resin such as an EMC may be injected into the encapsulation mold 10. Although the encapsulation mold 10 accommodates only one semiconductor chip 110 including a single chip or a plurality of stacked chips according to FIG. 3C, a plurality of semiconductor chips 110 may be aligned in a horizontal direction in the encapsulation mold 10. In this case, a process of individualizing a plurality of semiconductor packages after they are completely molded may be further included.

As described above, because the upper mold 10a closely contacts the upper surface of the spacer 140, although a pressure applied to the encapsulant 150 in a molding process is not considerably high, the encapsulant 150 may sufficiently cover the upper surface of the semiconductor chip 110 in cooperation with the spacer 140. If the spacer 140 does not exist, the encapsulant 150 has to solely cover the entire upper surface of the semiconductor chip 110. For example, the encapsulant 150 has to flow to the center of the upper surface of the semiconductor chip 110, and thus a considerably high pressure is required to apply the encapsulant 150. For example, if a distance between the upper mold 10a and the semiconductor chip 110 is very small, for example, equal to or less than about 200 μm, due to a viscosity and a surface tension of the encapsulant 150, considerably high pressure may be required to be applied to the encapsulant 150 so that the encapsulant 150 uniformly covers the entire upper surface of the semiconductor chip 110.

Where a plurality of semiconductor chips 110 are aligned in a horizontal direction in the encapsulation mold 10, near an inlet of the encapsulant 150, the encapsulant 150 has a relative low viscosity and thus may easily and sufficiently cover the upper surface of the semiconductor chip 110. However, because the viscosity of the encapsulant 150 increases as time passes, e.g., as the encapsulant progresses in to the mold 10, the entire upper surface of the semiconductor chip 110 that is placed away from the inlet of the encapsulant 150 may not be easily and/or uniformly covered by the encapsulant 150 . By providing the spacer 140, the encapsulant 150 may easily cover the entire upper surface of the semiconductor chip 110 in cooperation with the spacer 140.

In the event that the horizontal distance w between an edge of the semiconductor chip 110 and an edge of the spacer 140 is excessively large, an excessive pressure may be required to allow the encapsulant 150 to flow to reach the edge of the spacer 140. In this case, the encapsulant 150 may be hardened during the flow and fail to reach the spacer 140 in a horizontal direction. As a result, the upper surface of the semiconductor chip 110 may be partially exposed. Accordingly, the horizontal distance w between an edge of the semiconductor chip 110 and an edge of the spacer 140 needs to be appropriate, for example, equal to or less than about 500 μm, equal to or less than about 200 μm, or equal to or less than about 150 μm.

The upper mold 10a may tightly contact the entire upper surface of the spacer 140 or, in some cases, may not fully contact a partial region of the upper surface of the spacer 140. In the event that the upper mold does not fully contact the partial region of the upper surface of the spacer 140, the encapsulant 150 may flow between the upper mold 10a and the spacer 140, and may be hardened and may remain as flash on the upper surface of the spacer. FIG. 4 is a perspective view of the semiconductor package 100 illustrated in FIG. 3C, when flash 155 remains on the upper surface of the spacer 140.

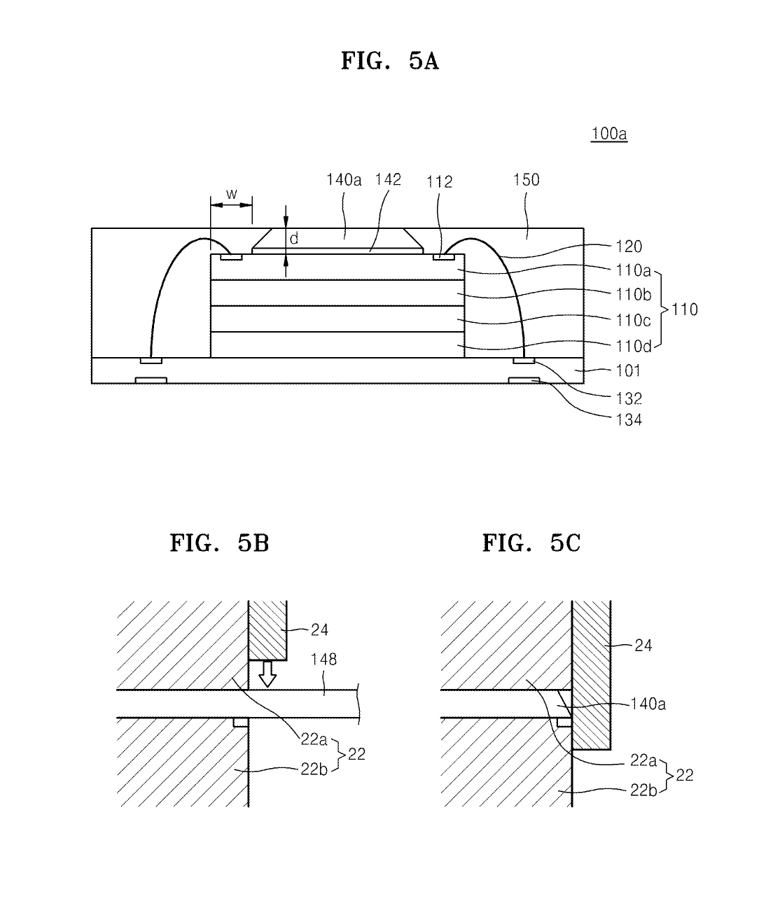

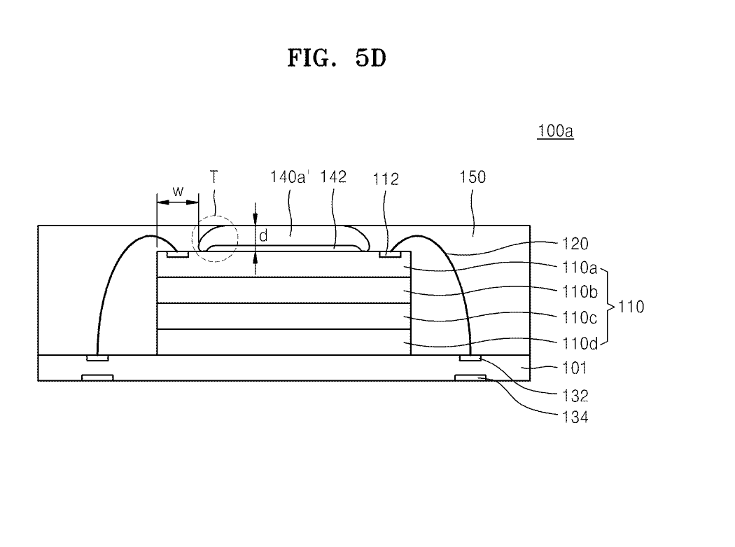

FIG. 5A is a cross-sectional view of a semiconductor package 100a according to an example embodiment. FIGS. 5B and 5C are conceptual cross-sectional views for describing a method of forming a spacer 140a to be used in the semiconductor package 100a illustrated in FIG. 5A. Except for the spacer 140a, the semiconductor package 100a illustrated in FIG. 5A is the same as the semiconductor package 100 illustrated in FIGS. 1B, and 3A through 3C, and thus detailed descriptions of elements other than the spacer 140a are not provided here.

Referring to FIG. 5A, as in FIG. 1B, the spacer 140a is formed on the semiconductor chip 110. The spacer 140a may have a transverse width that varies in a direction away from the semiconductor chip 110.

In more detail, the spacer 140a may have a transverse width that decreases in a direction away from the semiconductor chip 110. For example, side surfaces of the spacer 140a may be inclined by a certain angle with respect to the upper surface of the semiconductor chip 110. For example, the side surfaces of the spacer 140a may be inclined inward in a direction away from the semiconductor chip 110.

Furthermore, although the side surfaces of the spacer 140a are flat in FIG. 5A, the side surfaces of the spacer 140a do not have to be flat and may be curved. For example, the side surfaces of the spacer 140a may be convex outward. Also, although portions where upper and side surfaces of the spacer 140a meet each other are cornered in FIG. 5A, the portions may be curved.

A method of forming the above-described spacer 140a is not limited to a particular method. For example, as illustrated in FIG. 5B, the spacer 140a may be formed by punching a flat panel 148 of a material. For example, the spacer 140a having a desired size may be obtained by fixing the flat panel 148 with dies 22, which includes upper and lower dies 22a and 22b, and then lowering a punch 24 along side surfaces of the dies 22 to punch the flat panel 148.

The side surfaces of the spacer 140a may not be vertically straight, but may be inclined as illustrated in FIG. 5C due to shear stress applied to the flat panel 148 when it is punched by the punch 24. In order to form the spacer 140a in large quantities, for example, a plurality of stacked flat panels 148 may be fixed between the upper and lower dies 22a and 22b and punched together.

However, a forming process of the spacer 140a is not limited to the above method and may be formed by using other methods.

According to a process of forming the spacer 140a, at least a portion of the side surfaces of the spacer 140a may be roughened. For example, at least a portion of the side surfaces of the spacer 140a may be formed rougher than the upper surface of the spacer 140a. For example, burrs may be formed on the side surfaces of the spacer 140a.

As represented by T in FIG. 5D, an edge of a spacer 140a′ may be slightly bent downward. For example, at least a portion of the edge of the spacer 140a′ may be slightly bent toward the semiconductor chip 110. This deformation may be intended or may be caused by the above-described shear stress.

When the transverse width of a spacer varies in a direction away from the semiconductor chip 110, the edge of the spacer is defined as the edge position of a surface of the spacer, where the spacer contacts the semiconductor chip 110. For example, referring to the spacer 140a illustrated in FIG. 5A, because the edge of a lower surface of the spacer 140a, which contacts the semiconductor chip 110, is defined as the edge of the spacer 140a, a horizontal distance between the edge of the spacer 140a and the edge of the semiconductor chip 110 may be represented by w as denoted in FIG. 5A. The horizontal distance w between the edge of the semiconductor chip 110 and the edge of the spacer 140a in FIG. 5A may be, for example, equal to or less than about 500 μm, equal to or less than about 200 μm, or equal to or less than about 150 μm.

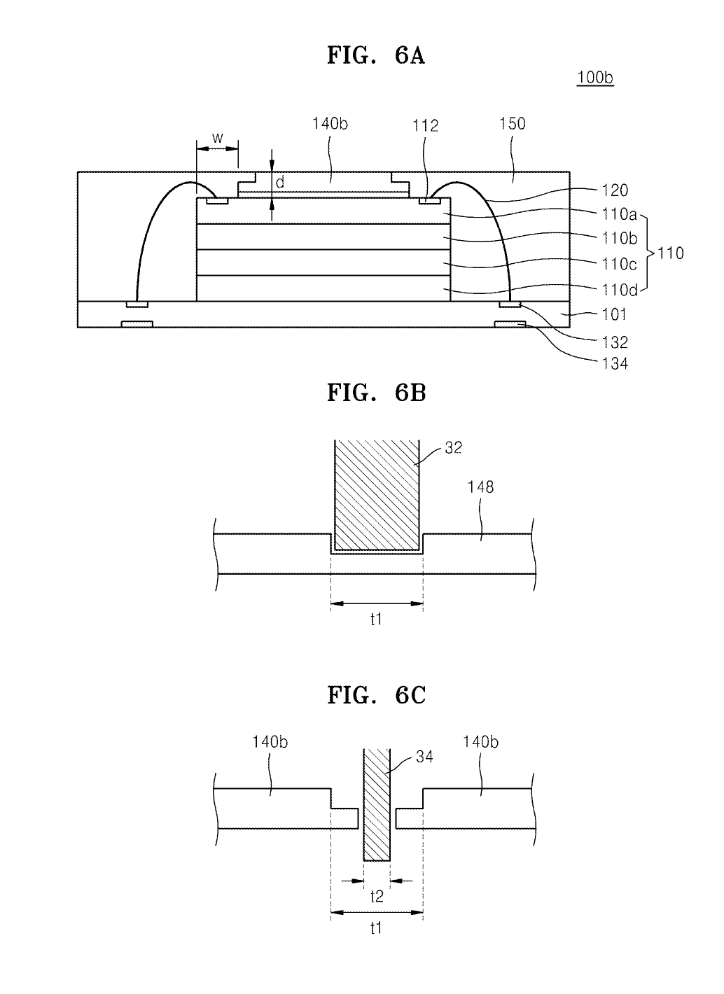

FIG. 6A is a cross-sectional view of a semiconductor package 100b according to an example embodiment. FIGS. 6B and 6C are conceptual cross-sectional views for describing a method of forming a spacer 140b to be used in the semiconductor package 100b illustrated in FIG. 6A. Except for the spacer 140b, the semiconductor package 100b illustrated in FIG. 6A is the same as the semiconductor package 100 illustrated in FIGS. 1B, and 3A through 3C, and thus detailed descriptions of elements other than the spacer 140b are not provided here.

Referring to FIG. 6A, as in FIG. 1B, the spacer 140b is formed on the semiconductor chip 110. The spacer 140b may be stepped or may have a transverse width that varies in a direction away from the semiconductor chip 110. Although the spacer 140b is stepped once in FIG. 6A, the spacer 140b may be stepped a plurality of times.

In more detail, the spacer 140b may have a certain width constantly maintained to a predetermined thickness in a direction away from the semiconductor chip 110. Also, the spacer 140b may have a width less than the certain width from the predetermined thickness to an upper surface of the spacer 140b.

The edge of the spacer 140b, for a purpose of defining the horizontal distance w between the edge of the spacer 140b and the edge of the semiconductor chip 110, may be defined as the edge of a lower surface of the spacer 140b which contacts the semiconductor chip 110. The horizontal distance w between the edge of the semiconductor chip 110 and the edge of the spacer 140b in FIG. 6A may be, for example, equal to or less than about 500 μm, equal to or less than about 200 μm, or equal to or less than about 150 μm.

A method of forming the above-described spacer 140b is not limited to a particular method. For example, as illustrated in FIG. 6B, the flat panel 148 of a material for forming the spacer 140b may be sawn to a desired (or alternatively, predetermined) first depth by using a first blade 32 having a first width t1. As a result, a recess having the first width t1 may be foamed in the flat panel 148.

Further, as illustrated in FIG. 6C, the flat panel 148 may be sawn at the center of the recess having the first width t1 by using a second blade 34 having a second width t2 and thus the flat panel 148 may be separated to form the spacers 140b. However, the spacer 140b is not limited to the above method and may be formed by using other methods.

Like the spacer 140a, according to a process of forming the spacer 140b, at least a portion of side surfaces of the spacer 140b may be roughened or may have burrs. For example, at least a portion of the side surfaces of the spacer 140b may be formed rougher than the upper surface of the spacer 140b.

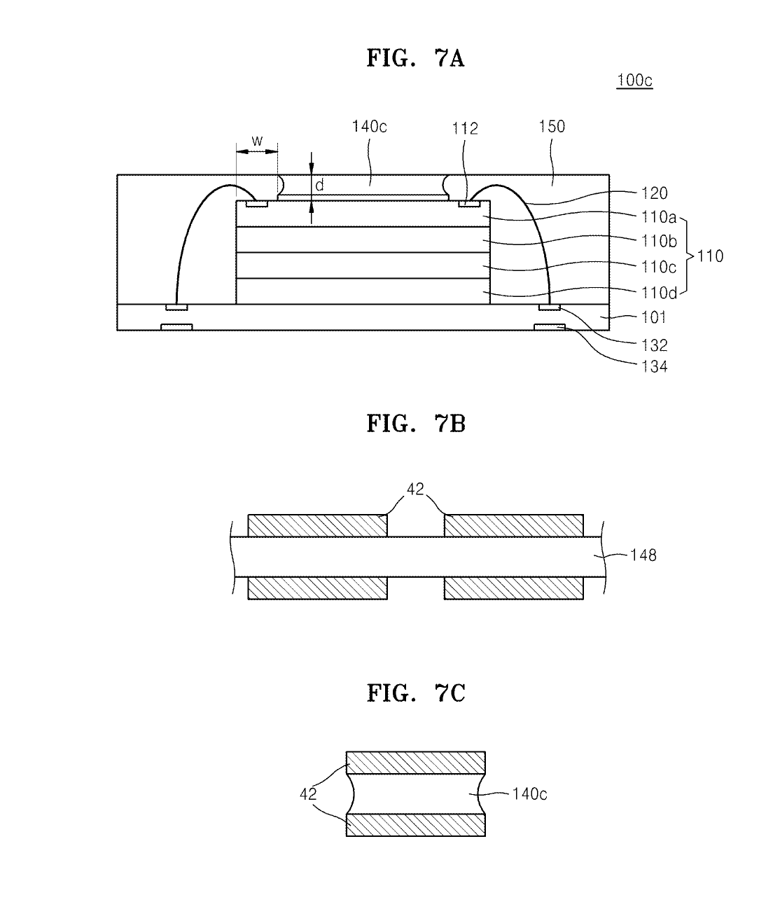

FIG. 7A is a cross-sectional view of a semiconductor package 100c according to an example embodiment. FIGS. 7B and 7C are conceptual cross-sectional views for describing a method of forming a spacer 140c to be used in the semiconductor package 100c illustrated in FIG. 7A. Except for the spacer 140c, the semiconductor package 100c illustrated in FIG. 7A is the same as the semiconductor package 100 illustrated in FIGS. 1B, and 3A through 3C, and thus detailed descriptions of elements other than the spacer 140c are not provided here.

Referring to FIG. 7A, as in FIG. 1B, the spacer 140c is formed on the semiconductor chip 110. The spacer 140c may have a first portion where a transverse width of the spacer 140c is reduced in a direction away from the semiconductor chip 110 to a first thickness. The spacer 140c may also have a second portion above the first portion where a transverse width of the spacer 140c is increased in a direction away from the semiconductor chip 110. For example, at least a portion of the spacer 140c may be recessed inward. At least a portion of the spacer 140c may be curved and concave inward.

The edge of the spacer 140c, for a purpose of defining the horizontal distance w between the edge of the spacer 140c and the edge of the semiconductor chip 110, may be defined as the edge of a lower surface of the spacer 140c, which contacts the semiconductor chip 110. The horizontal distance w between the edge of the semiconductor chip 110 and the edge of the spacer 140c in FIG. 7A may be, for example, equal to or less than about 500 μm, equal to or less than about 200 μm, or equal to or less than about 150 μm.

A method of forming the above-described spacer 140c is not limited to a particular method. Referring to FIG. 7B, etching masks 42 may be symmetrically formed on upper and lower surfaces of the flat panel 148 of a material to form the spacer 140c. The etching masks 42 may be photo-lithographically formed by using a photoresist material, or may be formed by using a tape bonding method. A material forming the etching masks 42 may be a material having an etch selectivity against the flat panel 148 with respect to an etchant to be applied later, and is not limited to a particular material.

Further, referring to FIG. 7C, the etchant may be applied to the flat panel 148 onto which the etching masks 42 are bonded. The etchant may be applied by using a wet etching method. In the event that the flat panel 148 may be immersed in the wet etchant, the flat panel 148 may be etched and individualized into the spacers 140c and side surfaces of the spacer 140c may be curved and concaved inward.

Thereafter, the spacer 140c may be obtained by removing the etching masks 42 formed on upper and lower surfaces of the spacer 140c. However, a method of forming the spacer 140c is not limited to the above method and may be formed by using other methods.

Like the spacer 140a, according to a process of forming the spacer 140c, at least a portion of the side surfaces of the spacer 140c may be formed to be relatively rough or may have burrs. For example, at least a portion of the side surfaces of the spacer 140c may be formed to be relatively roughen than the upper surface of the spacer 140c.

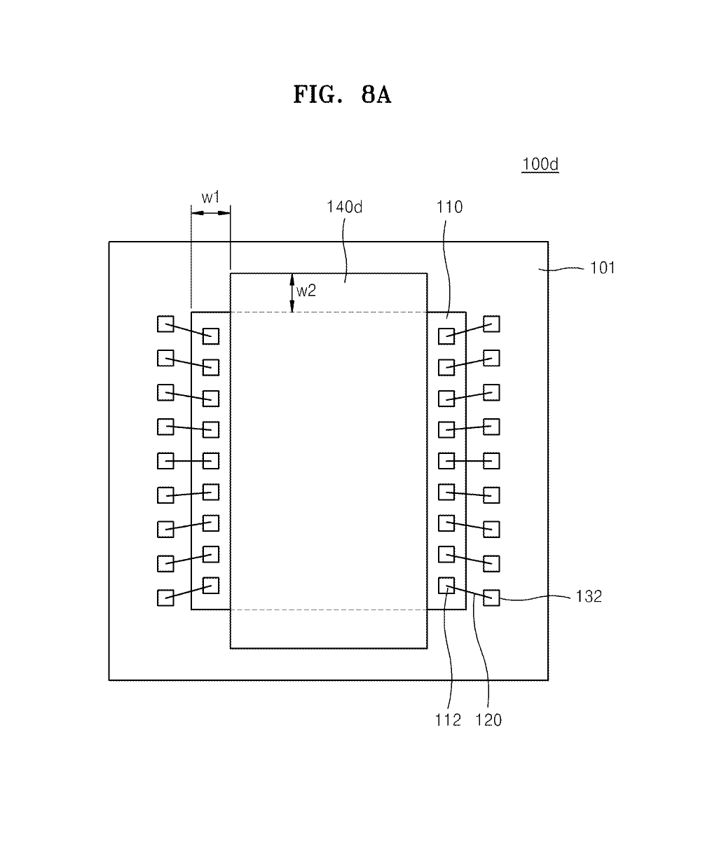

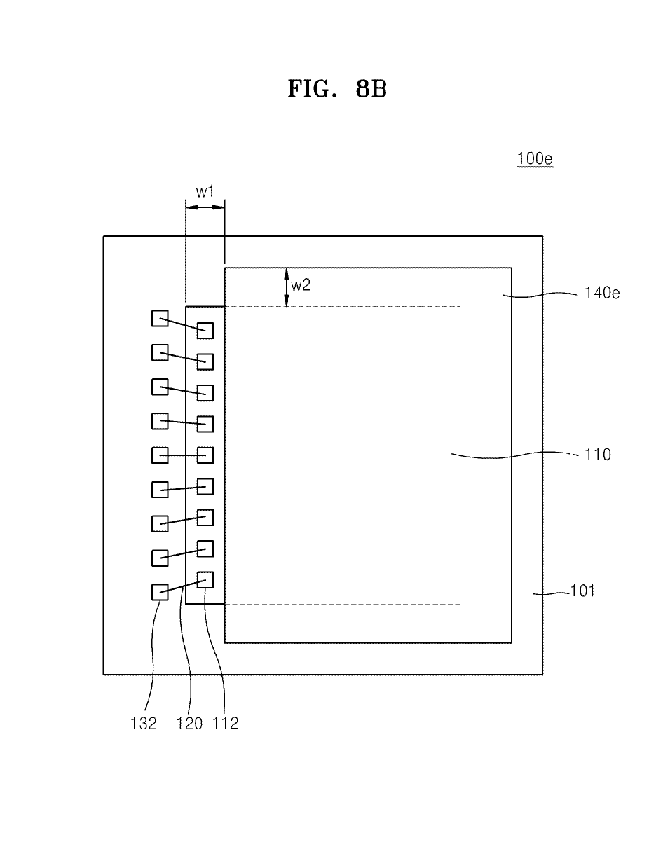

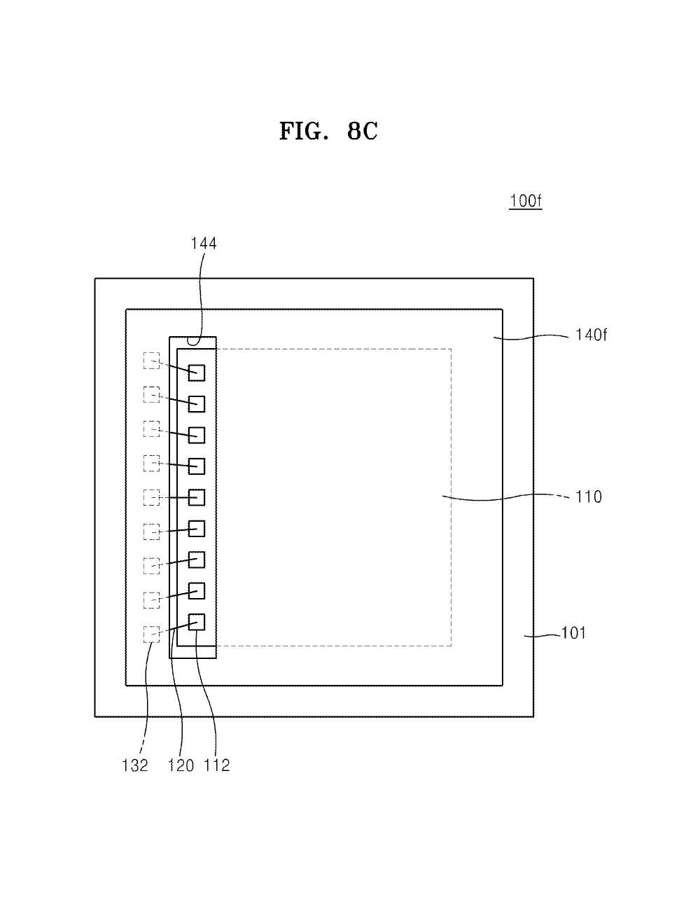

FIGS. 8A through 8C are plan views of semiconductor packages 100d, 100e, and 100f according to an example embodiments.

Referring to FIG. 8A, the semiconductor package 100d includes a spacer 140d.

At least a portion of the spacer 140d may protrude from the edge of the semiconductor chip 110. For example, a horizontal distance w1 between the edge of the semiconductor chip 110 and the edge of the spacer 140d in a direction in which the spacer 140d does not protrude may be, for example, equal to or less than about 500 μm, equal to or less than about 200 μm, or equal to or less than about 150 μm, as described above referring to FIG. 1B. A horizontal distance w2 between the edge of the semiconductor chip 110 and the edge of the spacer 140d in a direction in which the spacer 140d protrudes may also be, for example, equal to or less than about 500 μm, equal to or less than about 200 μm, or equal to or less than about 150 μm, to prevent an excessive side effect due to overhang.

Referring to FIG. 8B, the semiconductor package 100e includes a spacer 140e.

A plurality of bonding pads 112 may be formed along only one edge of the semiconductor chip 110. For example, the spacer 140e may protrude from the edge of the semiconductor chip 110, along which the bonding pads 112 are not formed. For example, as described above referring to FIG. 8A, each of the horizontal distances w1 and w2 between the edge of the semiconductor chip 110 and the edge of the spacer 140e may be, for example, equal to or less than about 500 μm, equal to or less than about 200 μm, or equal to or less than about 150 μm.

Referring to FIG. 8C, the semiconductor package 100f includes a spacer 140f.

The entire edge of the spacer 140f may protrude from the edge of the semiconductor chip 110. For example, to ensure a space where the connectors 120 connect the bonding pads 112 formed on an active surface of the semiconductor chip 110 to the bonding pads 132 formed on the circuit board 101, the spacer 140f may include an opening 144. Although the bonding pads 112 are formed along only one edge of the semiconductor chip 110 in FIG. 8C, it would be understood by one of ordinary skill in the art that the bonding pads 112 may be additionally formed along an another edge of the semiconductor chip 110, and thus the spacer 140f may include another opening.

For example, an area of a lower surface of the spacer 140f may be greater than the area of the upper surface of the semiconductor chip 110 that is an individual semiconductor die on which the spacer 140f is disposed.

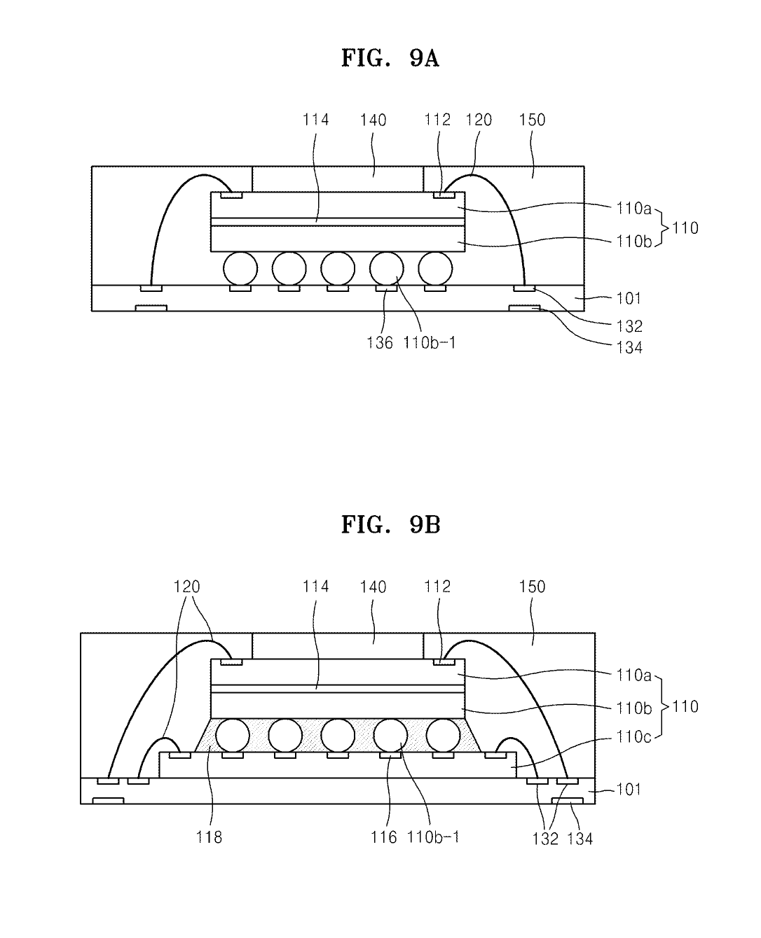

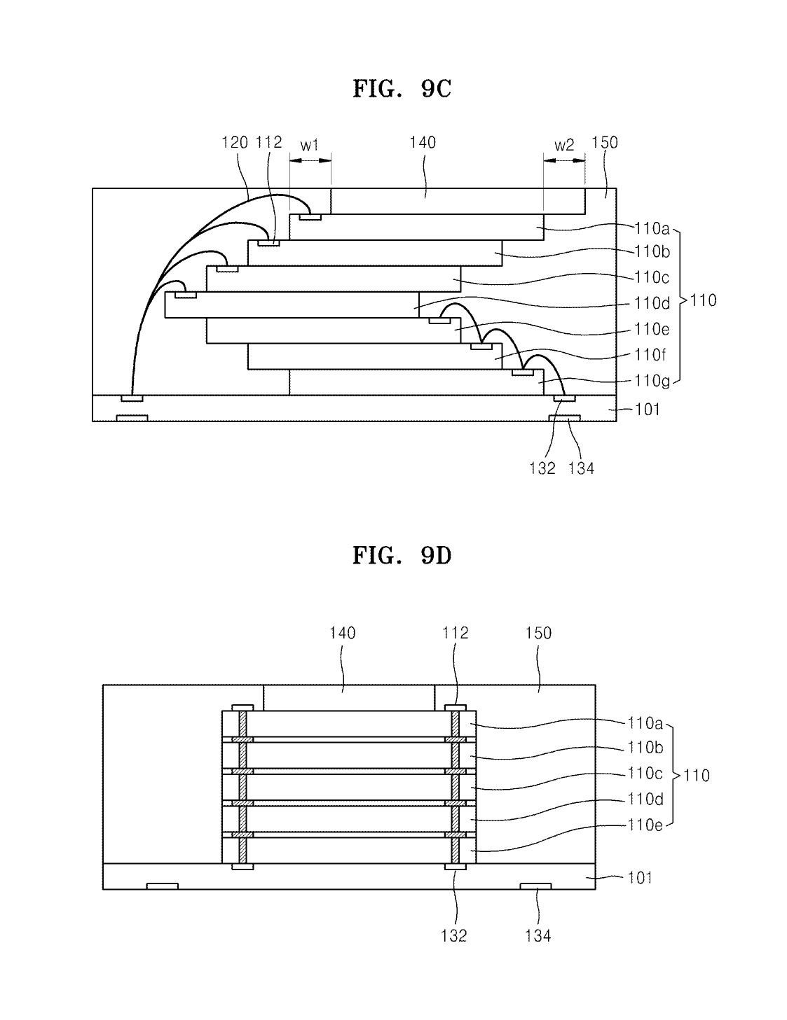

FIGS. 9A through 9D are cross-sectional views of semiconductor packages according to example embodiments.

Referring to FIG. 9A, the first and second semiconductor chips 110a and 110b may be mounted on the circuit board 101. For example, the second semiconductor chip 110b may be directly mounted on the circuit board 101 in the form of a flip-chip. The second semiconductor chip 110b may be connected via a plurality of solder bumps 110b-1 to a plurality of bump pads 136 formed on the circuit board 101.

The first semiconductor chip 110a may be provided on the second semiconductor chip 110b. The first semiconductor chip 110a may be bonded onto the second semiconductor chip 110 by using, for example, a bonding member 114, such that an active surface of the first semiconductor chip 110a faces upward. The bonding member 114 may be, for example, an NCF, an ACF, a UV-sensitive film, an instant adhesive, a thermosetting adhesive, a laser-curable adhesive, an ultrasound-curable adhesive, or NCP.

The bonding pads 112 may be formed on the active surface of the first semiconductor chip 110a, and may be electrically connected via the connectors 120 to the bonding pads 132 on the circuit board 101. The connectors 120 may be, for example, bonding wires.

The spacer 140 may be formed on the first semiconductor chip 110a. The semiconductor chip 110 may be encapsulated with the encapsulant 150. For example, the upper surface of the spacer 140 may be exposed externally. Also, a level of the upper surface of the spacer 140 may be substantially the same as the level of the upper surface of the encapsulant 150.

Referring to FIG. 9B, elements other than the first through third semiconductor chips 110a through 110c mounted on the circuit board 101 are the same as those illustrated in FIG. 9A, and thus detailed descriptions thereof are not provided here.

The semiconductor chip 110 may include a plurality of semiconductor chips stacked in the form of chip-on-chip (CoC). Referring to FIG. 9B, the semiconductor chip 110 may include the first through third semiconductor chips 110a through 110c. The second and third semiconductor chips 110b and 110c may be connected to each other in the form of CoC via the solder bumps 110b-1 and a plurality of bump pads 116. An underfill 118 may be further formed between the second and third semiconductor chips 110b and 110c.

Referring to FIG. 9C, elements other than first through seventh semiconductor chips 110a through 110g mounted on the circuit board 101 are the same as those illustrated in FIG. 9A, and thus detailed descriptions thereof are not provided here.

The first through seventh semiconductor chips 110a through 110g may be stacked on one another and may be offset from each other by a predetermined distance to expose the bonding pads 112. For example, an offset direction may be only one direction or may be two opposite directions as illustrated in FIG. 9C. However, the offset direction is not limited thereto and may include two or more arbitrary directions.

For example, each of the horizontal distances w1 and w2 between the edge of the spacer 140 and the edge of the first semiconductor chip 110a, which is a top semiconductor chip may be, for example, equal to or less than about 500 μm, equal to or less than about 200 μm, or equal to or less than about 150 μm.

If the active surface of the first semiconductor chip 110a, which is a top semiconductor chip, faces upward and is connected to the circuit board 101 via bonding wires as illustrated in FIGS. 9A through 9C, due to loops of the bonding wires, the thickness of the spacer 140 may not be easily reduced.

FIG. 9D is a cross-sectional view showing an example using TSVs. Although the active surface of the first semiconductor chip 110a that is a top semiconductor chip faces upward, it may be electrically connected via TSVs to the second through fifth semiconductor chips 110b through 110e under the first semiconductor chip 110a. Because loops of bonding wires do not need to be formed, the spacer 140 may be formed to have an extremely small thickness.

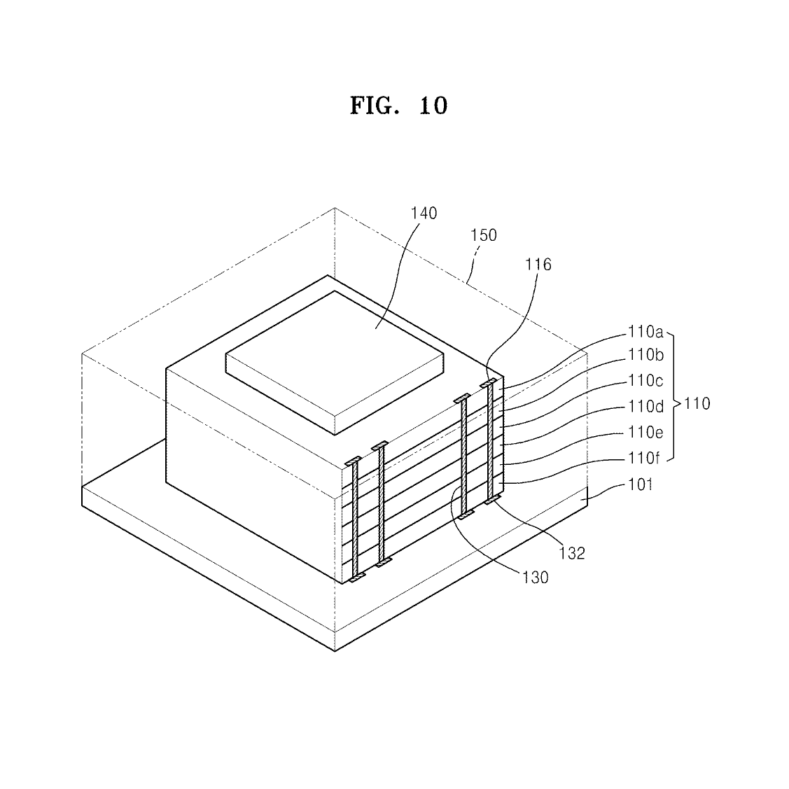

As another example of achieving a very small thickness of the spacer 140, side interconnection may be used as illustrated in FIG. 10. FIG. 10 is a perspective view of the first through sixth semiconductor chips 110a through 110f stacked and electrically connected to each other by using side interconnections 130, before being encapsulated with the encapsulant 150, according to an example embodiment.

Referring to FIG. 10, the first through sixth semiconductor chips 110a through 110f are stacked and mounted on the circuit board 101. Among the first through sixth semiconductor chips 110a through 110f, the active surface of the first semiconductor chip 110a, which is a top semiconductor chip, may face upward.

On an upper surface of the first semiconductor chip 110a, which is a top semiconductor chip, connection terminals 116 electrically connected to semiconductor devices in the first semiconductor chip 110a may be formed along an edge of the first semiconductor chip 110a. Also, on an upper and/or lower surface of each of the second through sixth semiconductor chips 110b through 110f, the connection terminals 116 electrically connected to semiconductor devices in each of the second through sixth semiconductor chips 110b through 110f may be formed along an edge of each of the second through sixth semiconductor chips 110b through 110f. The connection terminals 116 of the first through sixth semiconductor chips 110a through 110f may be electrically connected to each other by using the side interconnections 130.

Furthermore, the side interconnections 130 may be electrically connected to the bonding pad 132 formed on the upper surface of the circuit board 101. The bonding pad 132 formed on the upper surface of the circuit board 101 may be electrically connected to additional connection terminals formed on the lower surface of the circuit board 101.

Because the first semiconductor chip 110a, which is a top semiconductor chip, may be electrically connected to the second through sixth semiconductor chips 110b through 110f and/or the circuit board 101 without using bonding wires in FIG. 10, the spacer 140 may have an extremely small thickness.

In FIG. 9D and/or FIG. 10, the thickness of the spacer 140 may be about 5 μm to about 30 μm, or about 5 μm to about 20 μm.

FIG. 11 is a block diagram of a memory card 200 including the above semiconductor package, according to an example embodiment.

The memory card 200 includes a memory controller 220 for generating command and address (C/A) signals, and a memory module 210 such as a flash memory including one or a plurality of flash memory devices. The memory controller 220 includes a host interface 223 for transmitting or receiving the C/A signals to or from a host, and a memory interface 225 for transmitting or receiving the C/A signals to or from the memory module 210. The host interface 223, a controller 224, and the memory interface 225 communicate via a common bus 260 with a controller memory 221, e.g., static random-access memory (SRAM), and a processor 222, e.g., a central processing unit (CPU).

The memory module 210 receives the C/A signals from the memory controller 220, and, as a response, stores or searches for data in at least one of memory devices of the memory module 210. Each memory device includes a plurality of addressable memory cells and a decoder for receiving the C/A signals and generating row and column signals to access at least one of the addressable memory cells in programming and read operations.

At least one of the components of the memory card 200, e.g., the electronic devices (221, 222, 223, 224, and 225) included in the memory controller 220 and the memory module 210, may include a semiconductor package according to an example embodiment.

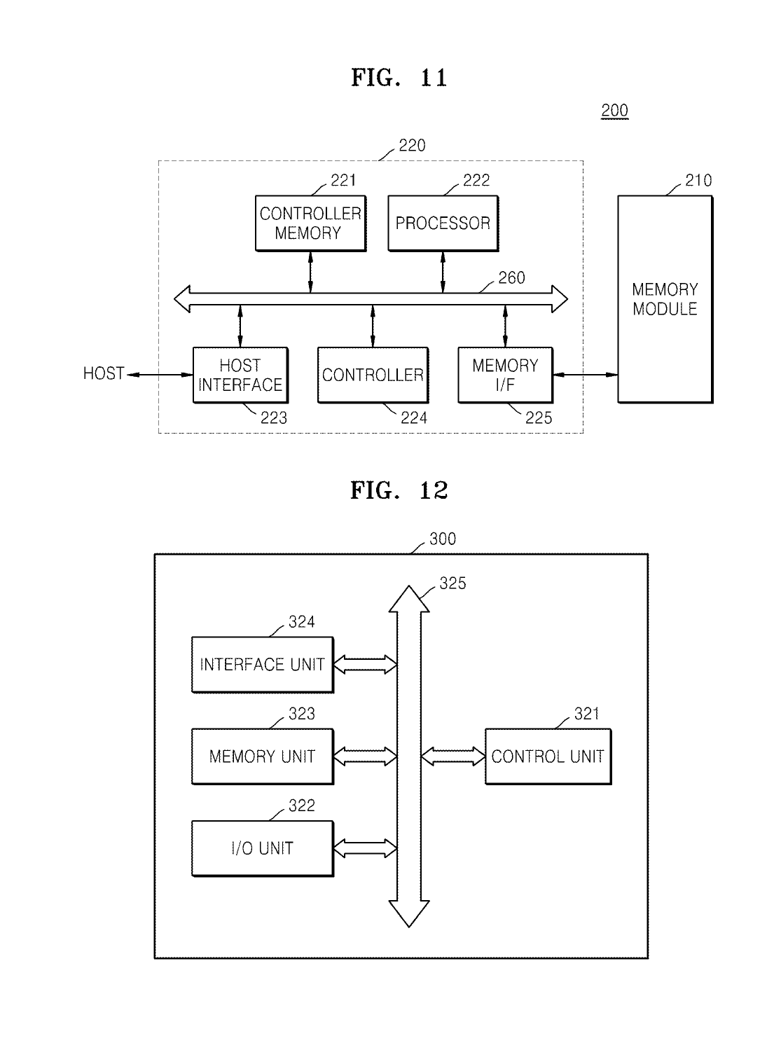

FIG. 12 is a conceptual view of a system 300 according to an example embodiment.

Referring to FIG. 12, the system 300 may include a control unit 321, an input/output (I/O) unit 322, a memory unit 323, and an interface unit 324.

The system 300 may be a mobile system or a system for transmitting or receiving information. The mobile system may be a personal digital assistant (PDA), a portable computer, a web tablet, a wireless phone, a mobile phone, a digital music player, or a memory card.

The control unit 321 may execute a program and may control the system 300. The control unit 321 may be, for example, a microprocessor, a digital signal processor, a micro controller, or the like. The control unit 321 may include a semiconductor package according to an example embodiment.

The I/O unit 322 may be used to input or output data of the system 300. The system 300 may be connected to an external apparatus such as a personal computer (PC) or a network and may exchange data with the external apparatus by using the I/O unit 322. The I/O unit 322 may be, for example, a keypad, a keyboard, or a display.

The memory unit 323 may store codes and/or data for operating the control unit 321, and/or may store data processed by the control unit 321. The memory unit 323 may include a semiconductor package according to an example embodiment.

The interface unit 324 may function as a data path between the system 300 and an external apparatus. The control unit 321, the I/O unit 322, the memory unit 323, and the interface unit 324 may communicate with each other via a bus 325. For example, the system 300 may be used in a mobile phone, an MP3 player, a navigator, a portable multimedia player (PMP), a solid state disk (SSD), or a household appliance.

While the inventive concepts have been particularly shown and described with reference to example embodiments thereof, it will be understood that various changes in form and details may be made therein without departing from the spirit and scope of the following claims.

What is claimed is:

1. A semiconductor package comprising:
a circuit board;
at least one semiconductor chip mounted on the circuit board;
a spacer disposed on the at least one semiconductor chip, an upper surface of the spacer exposed externally; and
an encapsulant covering side surfaces of the at least one semiconductor chip and the spacer.

2. The semiconductor package of claim 1, wherein the spacer has a thickness of abour 5 μm to about 110 μm

3. The semiconductor package of claim 1, wherein the upper surface of the spacer and an upper surface of the encapsulant are substantially coplanar.

4. The semiconductor package of claim 1, wherein a horizontal distance between an edge of the spacer and an edge of the at least one semiconductor chip is equal to or less than about 200 μm.

5. The semiconductor package of claim 4, wherein at least a portion of the edge of the spacer protrudes outside the at least one semiconductor chip.

6. The semiconductor package of claim 4, wherein at least a portion of the edge of the spacer is disposed on an upper surface of the at least one semiconductor chip.

7. The semiconductor package of claim 1, wherein at least a portion of side surfaces of the spacer is inclined inward in a direction away from the at least one semiconductor chip.

8. The semiconductor package of claim 1, wherein a transverse width of the spacer is reduced in a direction away from the at least one semiconductor chip.

9. The semiconductor package of claim 1, wherein at least a portion of side surfaces of the spacer is recessed inward.

10. The semiconductor package of claim 9, wherein the at least a portion of the side surfaces of the spacer is curved or concave inward.

11. The semiconductor package of claim 1, wherein at least a portion of side surfaces of the spacer is configured to be rougher than the upper surface of the spacer.

12. The semiconductor package of claim 1, wherein at least a portion of side surfaces of the spacer is stepped such that a width of an upper portion of the spacer is less than a width of a lower portion of the spacer.

13. The semiconductor package of claim 1, wherein the spacer is formed of a polymer, metal, or silicon.

14. The semiconductor package of claim 13, wherein the spacer is formed by stacking two or more layers formed of a polymer, metal, or silicon.

15. The semiconductor package of claim 1, wherein the at least one semiconductor chip includes at least two stacked semiconductor chips.

16. The semiconductor package of claim 15, wherein the at least two stacked semiconductor chips include at least one flip-chip.

17. The semiconductor package of claim 15, wherein a top semiconductor chip among the at least two stacked semiconductor chips includes a connection terminal on its upper surface.

18. The semiconductor package of claim 1, wherein the encapsulant leaves flash on at least a portion of the upper surface of the spacer.

19. The semiconductor package of claim 1, wherein an area of a lower surface of the spacer is greater than an area of an upper surface of the at least one semiconductor chip.

20. A semiconductor package comprising:
a circuit board;
at least one semiconductor chip mounted on the circuit board;
a spacer disposed on the at least one semiconductor chip; and
an encapsulant covering the at least one semiconductor chip, an upper surface of the encapsulant and an upper surface of the spacer are substantially coplanar .

21. The semiconductor package of claim 20, wherein an upper surface of the spacer is exposed externally.

22. The semiconductor package of claim 20, wherein at least a portion of an edge of the spacer is at least one of slightly bent downward and slightly bent toward the at least one semiconductor chip.

23. The semiconductor package of claim 20, wherein side surfaces of the spacer has a roughened surface or burrs.

24. The semiconductor package of claim 20, wherein the spacer has a thickness of about 5 μm to about 110 μm.

25. A system comprising:
a control unit;
an input/output (I/O) unit configured to input or output data;
a memory unit configured to store the data;
an interface unit configured to transmit or receive the data to or from an external apparatus; and
a bus configured to connect the control unit, the 110 unit, the memory unit, and the interface unit to communicate with each other,
wherein at least one of the control unit and the memory unit includes the semiconductor package of claim 1.

26. A method of manufacturing a semiconductor package, the method comprising:
mounting at least one semiconductor chip on a circuit board;
disposing a spacer on an upper surface of the at least one semiconductor chip; and
supplying an encapsulant to seal side surfaces and an exposed portion of the upper surface of the at least one semiconductor chip while a mold contacts the spacer.

27. A semiconductor package comprising:
a circuit board;
at least one semiconductor chip on the circuit board;
at least one spacer attached to an upper surface of the at least one semiconductor chip; and
an encapsulant covering the at least one semiconductor chip.

28. The semiconductor package of claim 27, further comprising:
a bonding layer between the at least one spacer and the at least one semiconductor chip, the bonding layer attaching the at least one spacer to the at least one semiconductor chip.

29. The semiconductor package of claim 27, wherein an upper surface of the encapsulant and an upper surface of the at least one spacer are substantially coplanar with a tolerance of about 2 μm.

30. The semiconductor package of claim 27, wherein the at least one spacer is formed of a single spacer.

31. The semiconductor package of claim 30, wherein a distance between an edge of an uppermost one of the at least one semiconductor chip and an edge of the single spacer is configured such that an encapsulant flows to reach the edge of the single spacer at a desired pressure.

32. The semiconductor package of claim 27, wherein an entire edge of the at least one spacer protrudes from an entire edge of an uppermost one of the at least one semiconductor chip.

33. The semiconductor package of claim 32, wherein the at least one spacer include an opening.
